(19) United States
(12) Patent Application Publication
(10) Pub. No.: US 2023/0421964 A1
(43) Pub. Date: Dec. 28, 2023

(54) PIEZOELECTRIC FILM AND LAMINATED PIEZOELECTRIC ELEMENT

(71) Applicant: FUJIFILM Corporation, Tokyo (JP)

(72) Inventor: Yoshinori Tamada, Minamiashigara-shi (JP)

(73) Assignee: FUJIFILM Corporation, Tokyo (JP)

(21) Appl. No.: 18/464,417

(22) Filed: Sep. 11, 2023

Related U.S. Application Data
(63) Continuation of application No. PCT/JP22/06340, filed on Feb. 17, 2022.

(30) Foreign Application Priority Data
Mar. 12, 2021 (JP) 2021-040030

(51) Int. Cl. H04R 17/00; H10N 30/85; H10N 30/88; H10N 30/092

(52) U.S. Cl. CPC H04R 17/00; H10N 30/852; H10N 30/883; H10N 30/092

(57) ABSTRACT

An object of the present invention is to provide a piezoelectric film that has satisfactory durability, is capable of outputting a sound with a high sound pressure, decreases the resistance of an electrode layer, and is capable of suppressing heat generation. The above-described object is achieved by providing the piezoelectric film including a piezoelectric layer containing piezoelectric particles in a matrix that contains a polymer material, electrode layers provided on both surfaces of the piezoelectric layer, and an interlayer provided on at least one side between the piezoelectric layer and the electrode layers, in which the interlayer contains carbon and/or a metal, and a metal atom concentration of 30 to 90 atm % or a carbon atom concentration of 85 to 95 atm % is satisfied.

### CROSS-REFERENCE TO RELATED APPLICATIONS

This application is a Continuation of PCT International Application No. PCT/JP2022/006340 filed on Feb. 17, 2022, which claims priority under 35 U.S.C. § 119(a) to Japanese Patent Application No. 2021-040030 filed on Mar. 12, 2021. The above applications are hereby expressly incorporated by reference, in their entirety, into the present application.

### BACKGROUND OF THE INVENTION

### 1. Field of the Invention

The present invention relates to a piezoelectric film used as an electroacoustic conversion film or the like, and a laminated piezoelectric element obtained by laminating the piezoelectric film.

### 2. Description of the Related Art

Flexible displays, such as organic EL displays, which are formed of flexible substrates such as plastics have been developed.

In a case where such a flexible display is used as an image display device also serving as a sound generator that reproduces a sound together with an image, such as a television receiver, a speaker which is an acoustic device for generating a sound is required.

Here, examples of typical shapes of speakers of the related art include a funnel-like so-called cone shape and a spherical dome shape. However, in a case where such a speaker is intended to be incorporated in the above-described flexible display, there is a concern that the lightness and the flexibility, which are advantages of the flexible display, are impaired. Further, in a case where the speaker is attached externally, since the speaker is troublesome to carry and difficult to install on a curved wall, there is a concern that a beautiful appearance is impaired.

Under the above-described circumstances, a piezoelectric film with flexibility has been suggested as a speaker that can be integrated with a flexible display without impairing the lightness and the flexibility.

For example, JP2014-209274A describes a piezoelectric film (electroacoustic conversion film) that includes a piezoelectric laminate including a piezoelectric layer (polymer-based piezoelectric composite material) formed by dispersing piezoelectric particles in a viscoelastic matrix consisting of a polymer material having a viscoelasticity at room temperature, electrode layers (thin film electrodes) provided on both surfaces of the piezoelectric layer, and protective layers provided on surfaces of the electrode layers and having an area less than or equal to the area of the piezoelectric layer, and a lead-out metal foil laminated on a part of the electrode layer and partially positioned outside the piezoelectric layer in a plane direction.

### SUMMARY OF THE INVENTION

The piezoelectric layer described in JP2014-209274A has excellent piezoelectric characteristics. Further, the piezoelectric layer is obtained by dispersing piezoelectric particles such as lead zirconate titanate particles in a polymer material such as cyanoethylated polyvinyl alcohol, and thus has satisfactory flexibility.

Therefore, according to the piezoelectric film formed of the piezoelectric layer, it is possible to obtain an electroacoustic conversion film or the like having flexibility and satisfactory piezoelectric characteristics, which can be used as, for example, a flexible speaker.

In order for such a piezoelectric film to operate properly, it is necessary that the electrode layer and the piezoelectric layer are bonded to each other with a sufficient bonding force.

However, in a case where the bonding force between the electrode layer and the piezoelectric layer is insufficient, the electrode layer and the piezoelectric layer may be peeled off from each other during long-term use at a high output and repeated winding, bending, stretching, and the like using the flexibility. Even in a case where the electrode layer and the piezoelectric layer are partially peeled off from each other, the part does not operate properly, and thus the sound pressure of the sound to be output is decreased, for example, in a case of a flexible speaker.

As a method of bonding the electrode layer and the piezoelectric layer with a high bonding force, a method of making the electrode layer and the piezoelectric layer adhere to each other with an adhesive as described in JP2014-209274A may be employed. In a case where the electrode layer and the piezoelectric layer adhere to each other with an adhesive, it is possible to prevent the electrode layer and the piezoelectric layer from being peeled off from each other for a long time and to obtain a flexible piezoelectric film having excellent durability.

However, an adhesive typically has a low dielectric constant. In addition, the piezoelectric film having electrode layers on both surfaces of the piezoelectric layer is in series as a circuit. Therefore, in a case where the electrode layers and the piezoelectric layer adhere to each other with an adhesive, the voltage is lost, and as a result, the sound pressure of the sound to be output is decreased.

An object of the present invention is to solve such problems of the related art and to provide a piezoelectric film including a piezoelectric layer that contains piezoelectric particles in a matrix containing a polymer material, and electrode layers on both surfaces of the piezoelectric layer, in which the piezoelectric film has satisfactory durability to prevent peeling between the piezoelectric layer and the electrode layer for a long time, is capable of outputting a sound with a high sound pressure, decreases the resistance of the electrode layer, and is capable of suppressing heat generation.

In order to achieve the above-described object, the present invention has the following configurations.
[1] A piezoelectric film comprising: a piezoelectric layer containing piezoelectric particles in a matrix that contains a polymer material; electrode layers provided on both surfaces of the piezoelectric layer; and an interlayer provided on at least one side between the piezoelectric layer and the electrode layers, in which the interlayer contains carbon and/or a metal, and any of a metal atom concentration of 30 to 90 atm % or a carbon atom concentration of 85 to 95 atm % is satisfied.
[2] The piezoelectric film according to [1], in which the interlayer has a thickness of 5 to 5000 nm.
[3] The piezoelectric film according to [1] or [2], in which a resistance value of a laminate of the interlayer and the electrode layer is 12Ω or less.
[4] The piezoelectric film according to any one of [1] to [3], in which the interlayer is provided on only one side between the electrode layers and the piezoelectric layer.
[5] The piezoelectric film according to any one of [1] to [4], further comprising: a protective layer provided on a surface of at least one of the electrode layers.
[6] The piezoelectric film according to any one of [1] to [5], in which the piezoelectric film is polarized in a thickness direction.
[7] The piezoelectric film according to any one of [1] to [6], in which the piezoelectric film has no in-plane anisotropy as a piezoelectric characteristic.
[8] The piezoelectric film according to any one of [1] to [7], further comprising: a lead-out wire which connects the electrode layers and an external power source.
[9] A laminated piezoelectric element formed by laminating a plurality of layers of the piezoelectric films according to any one of [1] to [8].

The laminated piezoelectric element according to [9], in which the piezoelectric films are polarized in a thickness direction, and polarization directions of adjacent piezoelectric films are opposite to each other.

The laminated piezoelectric element according to [9] or [10], in which the laminated piezoelectric element is formed by laminating a plurality of layers of the piezoelectric films by folding back the piezoelectric film one or more times.

The laminated piezoelectric element according to any one of [9] to [11], comprising: a bonding layer which bonds the adjacent piezoelectric films.

According to the present invention, it is possible to provide a piezoelectric film including a piezoelectric layer that contains piezoelectric particles in a matrix containing a polymer material, and electrode layers on both surfaces of the piezoelectric layer, in which the piezoelectric film has satisfactory durability to prevent peeling between the piezoelectric layer and the electrode layer for a long time, is capable of outputting a sound with a high sound pressure, decreases the resistance of the electrode layer, and is capable of suppressing heat generation.

### BRIEF DESCRIPTION OF THE DRAWINGS

FIG. 1 is a conceptual view illustrating an example of a piezoelectric film of the present invention.

FIG. 2 is a conceptual view for describing an example of a method of preparing the piezoelectric film.

FIG. 3 is a conceptual view for describing an example of a method of preparing the piezoelectric film.

FIG. 4 is a conceptual view for describing an example of a method of preparing the piezoelectric film.

FIG. 5 is a conceptual view for describing an example of a method of preparing the piezoelectric film.

FIG. 6 is a conceptual view illustrating an example of a piezoelectric speaker formed of the piezoelectric film illustrated in FIG. 1.

FIG. 7 is a conceptual view for describing a method of measuring a sound pressure in an example.

### DESCRIPTION OF THE PREFERRED EMBODIMENTS

Hereinafter, a piezoelectric film and a laminated piezoelectric element according to the embodiment of the present invention will be described in detail based on suitable examples shown in the accompanying drawings.

Descriptions of the configuration requirements described below may be made based on representative embodiments of the present invention, but the present invention is not limited to such embodiments.

In the present specification, a numerical range shown using “to” indicates a range including numerical values described before and after “to” as a lower limit value and an upper limit value.

In addition, the figures shown below are conceptual views for describing the present invention, and the thickness of each layer, the size of the piezoelectric particles, the size of the constituent members, and the like are different from the actual values.

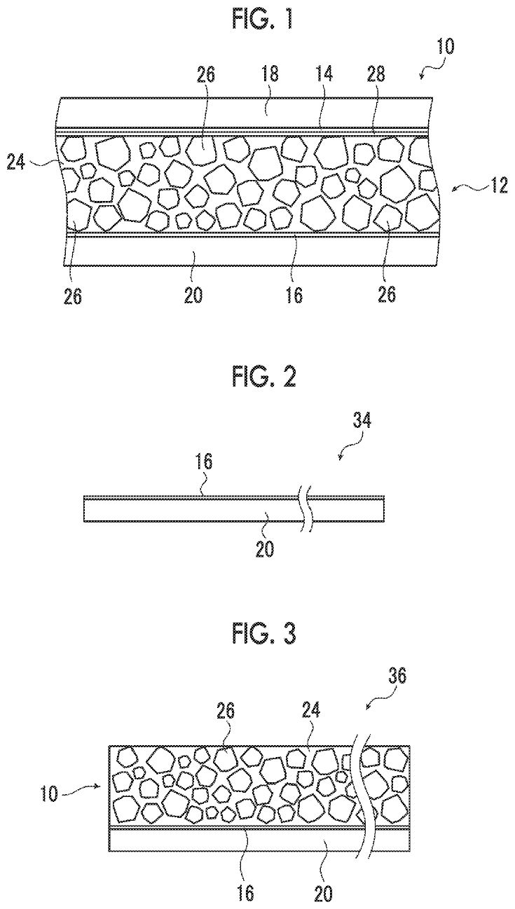

FIG. 1 conceptually illustrates an example of the piezoelectric film according to the embodiment of the present invention.

As illustrated in FIG. 1, the piezoelectric film 10 includes a piezoelectric layer 12, a first electrode layer 14 laminated on one surface of the piezoelectric layer 12, a first protective layer 18 laminated on the surface of the first electrode layer 14, a second electrode layer 16 laminated on the other surface of the piezoelectric layer 12, and a second protective layer 20 laminated on the surface of the second electrode layer 16.

In the piezoelectric film 10, the piezoelectric layer 12 contains piezoelectric particles 26 in a matrix 24 containing a polymer material, as conceptually illustrated in FIG. 1. As will be described below, the piezoelectric film 10, that is, the piezoelectric layer 12 is polarized in the thickness direction as a preferred aspect.

The piezoelectric film 10 according to the embodiment of the present invention includes an interlayer 28 between the piezoelectric layer 12 and the first electrode layer 14. The interlayer 28 acts as a bonding layer to which the piezoelectric layer 12 and the first electrode layer 14 are bonded.

In the present invention, the terms “first” and “second” in the first electrode layer 14 and the second electrode layer 16, and the first protective layer 18 and the second protective layer 20 are used to distinguish two similar members of the piezoelectric film 10 for convenience.

That is, the terms “first” and “second” of the respective constituent elements of the piezoelectric film 10 have no technical meaning.

Therefore, any of the first electrode layer 14 or the second electrode layer 16 may be coated for formation of the piezoelectric layer 12 described below, and accordingly, the interlayer 28 may be provided between the piezoelectric layer 12 and the first electrode layer 14 or between the piezoelectric layer 12 and the second electrode layer 16.

As described above, the piezoelectric layer 12 of the piezoelectric film 10 according to the embodiment of the present invention is formed by dispersing the piezoelectric particles 26 in the matrix 24 containing a polymer material. That is, the piezoelectric layer 12 is a polymer-based piezoelectric composite material.

Here, it is preferable that the polymer-based piezoelectric composite material (piezoelectric layer 12) satisfies the following requirements. Further, in the present invention, room temperature is in a range of 0° C. to 50° C.

(i) Flexibility

For example, in a case of being gripped in a state of being loosely bent like a document such as a newspaper or a magazine as a portable device, the piezoelectric film is continuously subjected to large bending deformation from the outside at a relatively slow vibration of less than or equal to a few Hz. In this case, in a case where the polymer-based piezoelectric composite material is hard, a large bending stress is generated to that extent, and a crack is generated at the interface between a polymer matrix and piezoelectric particles, which may lead to breakage. Accordingly, the polymer-based piezoelectric composite material is required to have suitable flexibility. In addition, in a case where strain energy is diffused into the outside as heat, the stress is able to be relaxed. Therefore, the polymer-based piezoelectric composite material is required to have a suitably large loss tangent.

(ii) Acoustic Quality

In a speaker, the piezoelectric particles vibrate at a frequency of an audio band of 20 Hz to 20 kHz, and the vibration energy causes the entire vibration plate (polymer-based piezoelectric composite material) to vibrate integrally so that a sound is reproduced. Therefore, in order to increase the transmission efficiency of the vibration energy, the polymer-based piezoelectric composite material is required to have appropriate hardness. In addition, in a case where the frequencies of the speaker are smooth as the frequency characteristic thereof, an amount of change in acoustic quality in a case where the lo west resonance frequency f₀ is changed in association with an amount of a change in the curvature of the speaker decreases. Therefore, the polymer-based piezoelectric composite material is required to have a suitably large loss tangent.

It is known that the lowest resonance frequency f₀ of the vibration plate for a speaker is represented by the following equation. Here, s represents the stiffness of the vibration system and m represents the mass.

Lowest resonance frequency:

$${f}_{0} = \frac{1}{2 π} \sqrt{\frac{s}{m}}$$

Here, as the degree of bending of the piezoelectric film, that is, the radius of curvature of the bendable portion increases, the mechanical stiffness s decreases, and thus the lowest resonance frequency f₀ decreases. That is, the acoustic quality (the volume and the frequency characteristics) of the speaker changes depending on the radius of curvature of the piezoelectric film.

That is, the flexible polymer-based piezoelectric composite material used as an electroacoustic conversion film is required to exhibit a behavior of being rigid with respect to a vibration of 20 Hz to 20 kHz and being flexible with respect to a vibration of less than or equal to a few Hz. In addition, the loss tangent of a polymer-based piezoelectric composite material is required to be suitably large with respect to the vibration of all frequencies of 20 kHz or less.

In general, a polymer solid has a viscoelasticity relaxing mechanism, and a molecular movement having a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relieving phenomenon is observed. A temperature at which this main dispersion occurs is a glass transition point (Tg), and the viscoelasticity relaxing mechanism is most remarkably observed.

In the polymer-based piezoelectric composite material (piezoelectric layer 12), the polymer-based piezoelectric composite material exhibiting a behavior of being rigid with respect to a vibration of 20 Hz to 20 kHz and being flexible with respect to a vibration of less than or equal to a few Hz is realized by using a polymer material whose glass transition point is room temperature, that is, a polymer material having a viscoelasticity at room temperature as a matrix. In particular, from the viewpoint that such a behavior is suitably exhibited, it is preferable that a polymer material in which the glass transition point at a frequency of 1 Hz is at room temperature, that is, in a range of 0° C. to 50° C. is used for a matrix of the polymer-based piezoelectric composite material.

As the polymer material having a viscoelasticity at room temperature, various known materials can be used. It is preferable that a polymer material in which the maximal value of a loss tangent Tanδ at a frequency of 1 Hz according to a dynamic viscoelasticity test at room temperature, that is, in a range of 0° C. to 50° is 0.5 or greater is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at room temperature, it is preferable that a storage elastic modulus (E′) at a frequency of 1 Hz according to the dynamic viscoelasticity measurement is 100 MPa or greater at 0° C. and 10 MPa or less at 50° C.

In this manner, the bending moment generated in a case where the polymer-based piezoelectric composite material is slowly bent due to the external force can be reduced, and the polymer-based piezoelectric composite material can exhibit a behavior of being rigid with respect to an acoustic vibration of 20 Hz to 20 kHz.

In addition, it is more suitable that the relative dielectric constant of the polymer material having a viscoelasticity at room temperature is 10 or greater at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring satisfactory moisture resistance and the like, it is suitable that the relative dielectric constant of the polymer material is 10 or less at 25° C.

Examples of the polymer material having a viscoelasticity at room temperature and satisfying such conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, it is preferable to use a material containing a cyanoethyl group and particularly preferable to use cyanoethylated PVA as the polymer material.

Further, these polymer materials in the matrix 24 may be used alone or in combination (mixture) of a plurality of kinds thereof.

A polymer material having no viscoelasticity at room temperature may also be added to the matrix 24 as necessary in addition to the polymer material having a viscoelasticity at room temperature.

That is, for the purpose of adjusting dielectric characteristics, mechanical characteristics, and the like, other dielectric polymer materials may be added to the matrix 24 in addition to the polymer material having a viscoelasticity at room temperature, such as cyanoethylated PVA, as necessary.

Examples of the dielectric polymer material that can be added thereto include a fluorine-based polymer such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, or a polyvinylidene fluoride-tetrafluoroethylene copolymer, a polymer containing a cyano group or a cyanoethyl group such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, or cyanoethyl sorbitol, and synthetic rubber such as nitrile rubber or chloroprene rubber.

Among these, a polymer material containing a cyanoethyl group is suitably used. Further, the number of kinds of the dielectric polymer materials to be added to the matrix 24 of the piezoelectric layer 12 in addition to the material having a viscoelasticity at room temperature, such as cyanoethylated PVA, is not limited to one, and a plurality of kinds of the materials may be added.

In addition, for the purpose of adjusting the glass transition point Tg, a thermoplastic resin such as a vinyl chloride resin, polyethylene, polystyrene, a methacrylic resin, polybutene, or isobutylene, and a thermosetting resin such as a phenol resin, a urea resin, a melamine resin, an alkyd resin, or mica may be added to the matrix 24 in addition to the dielectric polymer materials.

Further, for the purpose of improving the pressure sensitive adhesiveness, a viscosity imparting agent such as rosin ester, rosin, terpene, terpene phenol, or a petroleum resin may be added.

The addition amount of materials to be added to the matrix 24 of the piezoelectric layer 12 other than the polymer material having a viscoelasticity at room temperature such as cyanoethylated PVA is not particularly limited, but is preferably set to 30% by mass or less in terms of the proportion of the materials in the matrix 24.

In this manner, the characteristics of the polymer material to be added can be exhibited without impairing the viscoelasticity relaxing mechanism in the matrix 24, and thus preferable results, for example, an increase in the dielectric constant, improvement of the heat resistance, and improvement of the adhesiveness between the piezoelectric particles 26 and the electrode layer can be obtained.

In the piezoelectric film 10 according to the embodiment of the present invention, the piezoelectric layer 12 contains the piezoelectric particles 26 in such a matrix 24. Specifically, the piezoelectric layer 12 is a polymer-based piezoelectric composite material formed by dispersing the piezoelectric particles 26 in the matrix 24.

The piezoelectric particles 26 consist of ceramic particles having a perovskite type or wurtzite type crystal structure.

Examples of the ceramic particles constituting the piezoelectric particles 26 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

The piezoelectric particles 26 may be used alone or in combination (mixture) of a plurality of kinds thereof.

The particle diameter of the piezoelectric particles 26 is not limited, and may be appropriately selected according to the size, applications, and the like of the piezoelectric film 10.

The particle diameter of the piezoelectric particles 26 is preferably in a range of 1 to 10 μm. By setting the particle diameter of the piezoelectric particles 26 to be in the above-described range, preferable results in terms of achieving both excellent piezoelectric characteristics and flexibility of the piezoelectric film 10 can be obtained.

In FIG. 1, the piezoelectric particles 26 in the piezoelectric layer 12 are irregularly dispersed in the matrix 24, but the present invention is not limited thereto.

That is, the piezoelectric particles 26 in the piezoelectric layer 12 may be regularly dispersed in the matrix 24 as long as the piezoelectric particles 26 are preferably uniformly dispersed therein.

Further, the particle diameter of the piezoelectric particles 26 may or may not be uniform.

In the piezoelectric film 10, the ratio between the amount of the matrix 24 and the amount of the piezoelectric particles 26 in the piezoelectric layer 12 is not limited and may be appropriately set according to the size and the thickness of the piezoelectric film 10 in the plane direction, the applications of the piezoelectric film 10, the characteristics required for the piezoelectric film 10, and the like.

The volume fraction of the piezoelectric particles 26 in the piezoelectric layer 12 is preferably in a range of 30% to 80%, more preferably 50% or greater, and still more preferably in a range of 50% to 80%.

By setting the ratio between the amount of the matrix 24 and the amount of the piezoelectric particles 26 to be in the above-described ranges, preferable results in terms of achieving both of excellent piezoelectric characteristics and flexibility can be obtained.

Further, the thickness of the piezoelectric layer 12 in the piezoelectric film 10 is not particularly limited and may be appropriately set according to the applications of the piezoelectric film 10, the characteristics required for the piezoelectric film 10, and the like.

It is advantageous that the thickness of the piezoelectric layer 12 increases in terms of the rigidity such as the strength of stiffness of a so-called sheet-like material, but the voltage (potential difference) required to stretch and contract the piezoelectric film 10 by the same amount increases.

The thickness of the piezoelectric layer 12 is preferably in a range of 8 to 300 μm, more preferably in a range of 8 to 200 μm, still more preferably in a range of 10 to 150 μm, and particularly preferably in a range of 15 to 100 μm.

By setting the thickness of the piezoelectric layer 12 to be in the above-described ranges, preferable results in terms of achieving both ensuring of the rigidity and moderate elasticity can be obtained.

It is preferable that the piezoelectric layer 12, that is, the piezoelectric film 10 is subjected to a polarization treatment (poling) in the thickness direction. The polarization treatment will be described in detail below.

As illustrated in FIG. 1, the piezoelectric film 10 of the illustrated example has a configuration in which the first electrode layer 14 is provided on one surface of the piezoelectric layer 12, the first protective layer 18 is provided on the surface thereof, the second electrode layer 16 is provided on the other surface of the piezoelectric layer 12, and the second protective layer 20 is provided on the surface thereof. Further, the piezoelectric film according to the embodiment of the present invention further includes an interlayer 28 between the first electrode layer 14 and the piezoelectric layer 12.

Here, the first electrode layer 14 and the second electrode layer 16 form an electrode pair. That is, the piezoelectric film 10 has a configuration in which both surfaces of the piezoelectric layer 12 are sandwiched between the electrode pair, that is, the first electrode layer 14 and the second electrode layer 16, and the laminate is further sandwiched between the first protective layer 18 and the second protective layer 20.

In such a piezoelectric film 10, the region sandwiched between the first electrode layer 14 and the second electrode layer 16 stretches and contracts according to the applied voltage.

The first protective layer 18 and the second protective layer 20 in the piezoelectric film have a function of coating the first electrode layer 14 and the second electrode layer 16 and imparting moderate rigidity and mechanical strength to the piezoelectric layer 12. That is, the piezoelectric layer 12 consisting of the matrix 24 and the piezoelectric particles 26 in the piezoelectric film 10 exhibits extremely excellent flexibility under bending deformation at a slow vibration, but may have insufficient rigidity or mechanical strength depending on the applications. As a compensation for this, the piezoelectric film 10 is provided with the first protective layer 18 and the second protective layer 20.

In the piezoelectric film 10 of the illustrated example, the first protective layer 18 and the second protective layer 20 are provided to sandwich the laminate of the piezoelectric layer 12 and the electrode layers so as to correspond to both the first electrode layer 14 and the second electrode layer 16 as a preferable aspect.

In the piezoelectric film 10 according to the embodiment of the present invention, the first protective layer 18 and the second protective layer 20 are provided as a preferable aspect. Therefore, the piezoelectric film according to the embodiment of the present invention may have neither the first protective layer 18 nor the second protective layer 20 or may have only one of the first protective layer 18 or the second protective layer 20.

However, in consideration of the mechanical strength, the rigidity, the durability, and the like of the piezoelectric film in the present invention, it is preferable that the first protective layer 18 and the second protective layer 20 are provided to sandwich the laminate of the piezoelectric layer 12 and the electrode layers as the example of the piezoelectric film 10 illustrated in the figure.

The first protective layer 18 and the second protective layer 20 are not limited, and various sheet-like materials can be used, and suitable examples thereof include various resin films.

Among these, from the viewpoints of excellent mechanical characteristics and heat resistance, a resin film consisting of polyethylene terephthalate (PET), polypropylene (PP), polystyrene (PS), polycarbonate (PC), polyphenylene sulfide (PPS), polymethylmethacrylate (PMMA), polyetherimide (PEI), polyimide (PI), polyethylene naphthalate (PEN), triacetyl cellulose (TAC), and a cyclic olefin-based resin is suitably used.

The thickness of the first protective layer 18 and the second protective layer 20 is not limited. In addition, the thicknesses of the first protective layer 18 and the second protective layer 20 are basically the same as each other, but may be different from each other.

Here, in a case where the rigidity of the first protective layer 18 and the second protective layer 20 is extremely high, not only is the stretch and contraction of the piezoelectric layer 12 constrained, but also the flexibility is impaired. Therefore, it is advantageous that the thickness of the first protective layer 18 and the thickness of the second protective layer 20 decrease except for the case where the mechanical strength or satisfactory handleability as a sheet-like material is required.

In a case where the thickness of the first protective layer 18 and the second protective layer 20 in the piezoelectric film 10 is two times or less the thickness of the piezoelectric layer 12, preferable results in terms of achieving both ensuring of the rigidity and moderate elasticity can be obtained.

For example, in a case where the thickness of the piezoelectric layer 12 is 50 μm and the first protective layer 18 and the second protective layer 20 consist of PET, the thickness of the first protective layer 18 and the second protective layer 20 is preferably 100 μm or less, more preferably 50 μm or less, and still more preferably 25 μm or less.

In the piezoelectric film 10, the first electrode layer 14 is formed between the piezoelectric layer 12 and the first protective layer 18, and the second electrode layer 16 is formed between the piezoelectric layer 12 and the second protective layer 20. Further, the piezoelectric film 10 according to the embodiment of the present invention further includes an interlayer 28 between the piezoelectric layer 12 and the first electrode layer 14.

The first electrode layer 14 and the second electrode layer 16 are provided to apply a voltage to the piezoelectric layer 12 (piezoelectric film 10).

In the present invention, the material for forming the first electrode layer 14 and the second electrode layer 16 is not limited, and various conductors can be used as the material. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Among these, copper, aluminum, gold, silver, platinum, and indium tin oxide are suitable as the first electrode layer 14 and the second electrode layer 16.

In addition, a method of forming the first electrode layer 14 and the second electrode layer 16 is not limited, and a known method can be used. Examples thereof include a film forming method such as a vapor-phase deposition method (vacuum film forming method) such as vacuum vapor deposition or sputtering, a film forming method using plating, and a method of bonding a foil formed of the materials described above.

Among these, particularly from the viewpoint of ensuring the flexibility of the piezoelectric film 10, a thin film made of copper, aluminum, or the like formed by vacuum vapor deposition is suitably used as the first electrode layer 14 and the second electrode layer 16. Among these, particularly a thin film made of copper formed by vacuum vapor deposition is suitably used.

The thicknesses of the first electrode layer 14 and the second electrode layer 16 are not limited. In addition, the thicknesses of the first electrode layer 14 and the second electrode layer 16 are basically the same as each other, but may be different from each other.

Here, similarly to the first protective layer 18 and the second protective layer 20 described above, in a case where the rigidity of the first electrode layer 14 and the second electrode layer 16 is extremely high, not only is the stretch and contraction of the piezoelectric layer 12 constrained, but also the flexibility is impaired. Therefore, it is advantageous that the thicknesses of the first electrode layer 14 and the second electrode layer 16 decrease in a case where the electric resistance is not excessively high.

It is suitable that the product of the thickness and the Young's modulus of the first electrode layer 14 and the second electrode layer 16 of the piezoelectric film 10 is less than the product of the thickness and the Young's modulus of the first protective layer 18 and the second protective layer 20 from the viewpoint that the flexibility is not considerably impaired.

A combination of the first protective layer 18 and the second protective layer 20 which are formed of PET and the first electrode layer 14 and the second electrode layer 16 which are formed of copper may be considered as an example. In this case, the Young's modulus of PET is approximately 6.2 GPa, and the Young's modulus of copper is approximately 130 GPa. Therefore, in this case, in a case where the thickness of the first protective layer 18 and the second protective layer 20 is set to 25 μm, the thickness of the first electrode layer 14 and the second electrode layer 16 is preferably 1.2 μm or less, more preferably 0.3 μm or less, and still more preferably 0.1 μm or less.

As described above, the piezoelectric film 10 according to the embodiment of the present invention includes an interlayer 28 between the piezoelectric layer 12 and the first electrode layer 14. The interlayer 28 acts as a bonding layer (an adhesive layer or a pressure sensitive adhesive layer) for bonding the piezoelectric layer 12 and the first electrode layer 14.

Here, the interlayer 28 contains a metal or carbon (carbon particles) for imparting conductivity in addition to a component that serves as a bonding agent (binder). Specifically, the metal atom concentration in the interlayer 28 is in a range of 30 to 90 atom % (atm %) or the carbon atom concentration in the interlayer 28 is in a range of 85 to 95 atm %.

That is, the interlayer 28 acts as a bonding layer having conductivity. The piezoelectric film 10 according to the embodiment of the present invention including such an interlayer 28 enables prevention of peeling between the piezoelectric layer and the electrode layer for a long time, output of a sound with a high sound pressure, a decrease in the resistance of the electrode layer, and suppression of heat generation in the piezoelectric film in which the electrode layers are provided on both surfaces of the piezoelectric layer obtained by dispersing the piezoelectric particles in the matrix containing a polymer material.

As described below in an example, the piezoelectric film including electrode layers on both surfaces of the piezoelectric layer 12 and protective layers covering the electrode layers is prepared as follows.

First, a sheet-like material obtained by laminating the second protective layer 20 and the second electrode layer 16 and a sheet-like material obtained by laminating the first protective layer 18 and the first electrode layer 14 are prepared. In addition, a material serving as the matrix 24 is dissolved in a solvent to prepare a coating material in which the piezoelectric particles 26 are dispersed.

The second electrode layer 16 is coated with this coating material and dried, thereby preparing the piezoelectric layer 12.

Further, the sheet-like material is laminated on the piezoelectric layer 12 in a state where the sheet-like material faces the first electrode layer 14, heated, and pressure-bonded, to prepare the piezoelectric film 10.

Further, the terms “first” and “second” in the first electrode layer 14 and the second electrode layer 16 of the piezoelectric film 10 are used to distinguish two electrode layers from each other and have no technical meaning as described above.

Further, in the production of the piezoelectric film, for the purpose of flattening the surface of the piezoelectric layer 12, adjusting the thickness of the piezoelectric layer 12, and improving the density of the piezoelectric particles 26 in the piezoelectric layer 12 after the formation of the piezoelectric layer 12, it is preferable that the surface of the piezoelectric layer 12 is subjected to a calender treatment of pressing the surface using a heating roller or the like.

Here, the second electrode layer 16 coated with the coating material, which is formed into the piezoelectric layer 12, and the piezoelectric layer 12 are bonded to each other with a sufficient bonding force of the matrix 24 containing a polymer material.

Meanwhile, the bonding force between the first electrode layer 14 and the piezoelectric layer 12, which are heated and pressure-bonded to each other after the formation of the piezoelectric layer 12, is slightly insufficient.

In a case where the calender treatment is performed, the surface area of the matrix 24 having pressure sensitive adhesiveness on the first electrode layer 14 side of the piezoelectric layer 12 can be increased by embedding the piezoelectric particles 26 having no pressure sensitive adhesiveness in the piezoelectric layer 12. As a result, the bonding force between the first electrode layer 14 and the piezoelectric layer 12 can be improved. However, a sufficient bonding force between the piezoelectric layer 12 and the first electrode layer 14 may not be obtained even in a case where the calender treatment is performed.

Therefore, in the piezoelectric film including the electrode layers provided on both surfaces of the piezoelectric layer 12, the bonding force between the piezoelectric layer 12 and the first electrode layer 14 may be insufficient. In a case where the bonding force between the piezoelectric layer 12 and the first electrode layer 14 is insufficient, the piezoelectric layer 12 and the first electrode layer 14 with a weak bonding force may be peeled off from each other due to long-term use at a high output, repeated bending and stretching using flexibility, repeated winding, and the like.

As described above, in order for the piezoelectric film 10 to operate properly and output a sound with a high sound pressure, it is necessary that the piezoelectric layer 12 and the electrode layers are closely attached to each other properly. In a case where the piezoelectric layer 12 and the electrode layers are peeled off, since the peeled-off portion does not operate properly, the sound pressure of the sound to be output is decreased, for example, in a case of a flexible speaker even through the peeling has partially occurred.

As a method of solving such a problem, a method of bonding the piezoelectric layer 12 and the first electrode layer 14 with an adhesive, as described in JP2014-209274A, can be considered.

Here, in the piezoelectric film including the electrode layers on both surfaces of the piezoelectric layer 12, the sound pressure increases as the voltage applied to the piezoelectric particles 26 increases.

However, an adhesive typically has a low dielectric constant. Further, the piezoelectric film including the electrode layers on both surfaces of the piezoelectric layer 12 is in series as a circuit. Therefore, in a case where the electrode layers and the piezoelectric layer 12 adhere to each other with an adhesive, the voltage is lost, and as a result, the sound pressure of the sound to be output is decreased.

Meanwhile, the piezoelectric film 10 according to the embodiment of the present invention includes the interlayer 28 that is provided between the piezoelectric layer 12 and the first electrode layer 14, satisfies one of a metal atom concentration of 30 to 90 atm % or a carbon atom concentration of 85 to 95 atm %, and contains a component serving as a bonding agent.

That is, the piezoelectric film 10 according to the embodiment of the present invention includes the interlayer 28 that acts as a bonding layer having conductivity between the piezoelectric layer 12 and the first electrode layer 14.

Since the piezoelectric film 10 according to the embodiment of the present invention has such a configuration, the piezoelectric layer 12 and the first electrode layer 14 have a sufficiently high bonding force so that the peeling between the piezoelectric layer 12 and the first electrode layer 14 can be prevented even in a case of long-term use at a high output, repeated bending and stretching using the flexibility, repeated winding, and the like. That is, according to the present invention, the piezoelectric film 10 with high durability, which prevents a decrease in sound pressure caused by the peeling between the piezoelectric layer 12 and the first electrode layer 14 can be obtained.

Moreover, since the interlayer 28 has conductivity, loss of the voltage between the piezoelectric layer 12 and the first electrode layer 14 can be prevented, and thus a high voltage can be applied to the piezoelectric particles 26. Therefore, the piezoelectric film 10 according to the embodiment of the present invention can output a sound with a high sound pressure.

In addition, as described below, the piezoelectric film 10 according to the embodiment of the present invention is formed such that the resistance of the first electrode layer 14 (first electrode layer 14 side) is lower than that of a piezoelectric film of the related art that does not include the interlayer 28. Therefore, the piezoelectric film 10 according to the embodiment of the present invention can suppress the heat generation of the first electrode layer 14, and as a result, the heat generation of the piezoelectric film 10 can be suppressed.

As described below, the piezoelectric film 10 according to the embodiment of the present invention can be used as a so-called wearable speaker by being mounted on clothing, a portable item such as a bag, or the like. Therefore, the safety of a user with respect to the heat can be improved by suppressing the heat generation.

In addition, as described below, the piezoelectric film 10 according to the embodiment of the present invention can also be used as an exciter that outputs a sound to a vibration plate by vibrating the vibration plate. In this case, various devices (equipment), for example, a display device such as an organic electroluminescence display can also be used as the vibration plate. In this case, a device can be prevented from being additionally heated by suppressing the heat generation of the piezoelectric film 10. That is, a device that outputs a sound by being mounted on an exciter can be stably and safely driven by using the piezoelectric film 10 according to the embodiment of the present invention.

In the piezoelectric film 10 according to the embodiment of the present invention, the interlayer 28 contains a bonding agent (binder) and a metal atom or a carbon atom. Here, the carbon atom is a carbon atom that is not originated from the bonding agent, and specifically, is a carbon particle such as carbon black.

The bonding agent is not limited, and various kinds of bonding agents capable of bonding the piezoelectric layer 12 and the first electrode layer 14 (second electrode layer 16) can be used. Examples thereof include various polymer materials exemplified as the matrix 24 of the piezoelectric layer 12 described above. Further, a commercially available product can also be used as the bonding agent.

The bonding agent constituting the interlayer 28 may be an adhesive, a pressure sensitive adhesive, or a material having the characteristics of both the adhesive and the pressure sensitive adhesive. The adhesive is a bonding agent that has fluidity in a case of bonding layers and enters a solid state. The pressure sensitive adhesive is a bonding agent which is a gel-like (rubber-like) flexible solid in a case of bonding layers and whose gel-like state does not change thereafter.

The metal (metal atom) contained in the interlayer 28 is also not limited, and various metals can be used as long as the metals have conductivity. Examples thereof include platinum, gold, silver, copper, and nickel.

As the carbon particles, various known carbon particles such as carbon black can be used.

Further, a plurality of kinds of metals and carbon particles may be used in combination or the metal and the carbon particles may be used in combination in the interlayer 28.

In the piezoelectric film 10 according to the embodiment of the present invention, a case where the metal atom concentration or the carbon atom concentration of the interlayer 28 is high is advantageous in terms of the sound pressure of the sound to be output from the piezoelectric film 10 and the resistance value of the interlayer 28 which is the resistance of the first electrode layer 14, that is, the prevention of heat generation.

On the contrary, in the piezoelectric film 10 according to the embodiment of the present invention, a case where the metal atom concentration or the carbon atom concentration of the interlayer 28 is low is advantageous in terms of the durability, that is, the prevention of peeling between the piezoelectric layer 12 and the first electrode layer 14.

The interlayer 28 has a metal atom concentration of 30 to 90 atm % or a carbon atom concentration of 85 to 95 atm %.

In a case where the interlayer 28 has a metal atom concentration of less than 30 atm % or a carbon atom concentration of less than 85 atm %, inconveniences such as insufficient conductivity of the interlayer 28, a decrease in sound pressure of the sound to be output from the piezoelectric film, a high resistance value of the interlayer 28, and high heat generation occur.

In a case where the interlayer 28 has a metal atom concentration of greater than 90 atm % or a carbon atom concentration of greater than 95 atm %, inconveniences such as the insufficient bonding force and easy peeling between the piezoelectric layer 12 and the first electrode layer 14 occur.

The metal atom concentration of the interlayer 28 is preferably in a range of 40 to 80 atm % and more preferably in a range of 50 to 70 atm %.

Further, the carbon atom concentration of the interlayer 28 is preferably in a range of 87 to 95 atm % and more preferably in a range of 89 to 92 atm %.

In the present invention, the metal atom concentration and the carbon atom concentration of the interlayer 28 may be determined with a scanning electron microscope (SEM) equipped with energy dispersive X-ray spectrometry (EDX or EDS).

Specifically, the piezoelectric film 10 is cut in the thickness direction, and the cut surface is machined using a microtome or the like as necessary to expose the cross section.

Further, the thickness direction of the piezoelectric film 10 is a lamination direction of the protective layers, the electrode layers, and the piezoelectric layer. Further, the cross section of the piezoelectric film to be measured may be subjected to a conductive treatment of carrying out platinum vapor deposition or the like as necessary.

Next, the interlayer 28 on the cut surface is observed with the SEM equipped with EDX, and the metal atom concentration and/or the carbon atom concentration of the interlayer 28 during the observation is measured with the EDX.

In the present invention, the metal atom concentration and/or the carbon atom concentration of the interlayer 28 is measured at optional sites on optional 10 cross-sections of the piezoelectric film 10 to be measured, and the average value of the measured values from the ten sites is defined as the metal atom concentration and/or the carbon atom concentration of the interlayer 28 of the piezoelectric film 10 to be measured.

Further, in the piezoelectric film 10 according to the embodiment of the present invention, the concept of the carbon atoms in the carbon atom concentration of the interlayer 28 includes carbon atoms of the compound acting as the bonding agent in addition to the carbon atoms in the carbon particles added to impart conductivity to the interlayer 28.

In the piezoelectric film 10 according to the embodiment of the present invention, the thickness of the interlayer 28 is not limited.

It is advantageous that the thickness of the interlayer 28 decreases in terms of the sound pressure output from the piezoelectric film 10, particularly the initial sound pressure. On the contrary, it is advantageous that the thickness of the interlayer 28 increases in terms of the durability, that is, the prevention of the peeling between the piezoelectric layer 12 and the first electrode layer 14, and the resistance value of the interlayer 28 (first electrode layer 14), that is, the prevention of heat generation.

The thickness of the interlayer 28 is preferably in a range of 5 to 5000 nm. It is preferable that the thickness of the interlayer 28 is set to 5 nm or greater from the viewpoint that the peeling between the piezoelectric layer 12 and the first electrode layer 14, that is, a decrease in sound pressure due to long-term use can be suitably prevented, the resistance value of the interlayer 28 can be decreased, and the heat generation can be suitably prevented.

It is preferable that the thickness of the interlayer 28 is set to 5000 nm or less from the viewpoint that the piezoelectric film 10 can output a sound having a high sound pressure.

The thickness of the interlayer 28 is more preferably in a range of 10 to 3000 nm and still more preferably in a range of 10 to 1000 nm.

As described above, the piezoelectric film 10 according to the embodiment of the present invention is formed such that the resistance of the first electrode layer 14 (the electric resistance of the first electrode layer 14 side) is lower than that of a piezoelectric film of the related art that does not include the interlayer 28.

That is, in al piezoelectric film of the related art that does not include the interlayer 28, the resistance value of the first electrode layer 14 is determined only by the first electrode layer 14.

Meanwhile, the piezoelectric film 10 according to the embodiment of the present invention includes the interlayer 28 adjacent to the first electrode layer 14. As described above, the interlayer 28 has a metal atom concentration of 30 to 90 atm % or a carbon atom concentration of 85 to 95 atm % and has conductivity. Therefore, in the piezoelectric film 10 including the interlayer 28, the current supplied to the first electrode layer 14 can flow into the interlayer 28 in addition to the first electrode layer 14. That is, since the piezoelectric film 10 includes the interlayer 28, the number of flow paths of the current supplied to the first electrode layer 14 increases, and as a result, the resistance value of the first electrode layer 14 decreases.

Therefore, the piezoelectric film 10 according to the embodiment of the present invention can suitably prevent the heat generation of the first electrode layer 14, and as described above, can reduce the risk of the user due to the heat generation in a case of using the piezoelectric film 10 as a wearable speaker. Further, in a case where the piezoelectric film 10 according to the embodiment of the present invention is used as an exciter, heating of the device serving as a vibration plate is suppressed so that the device can be driven more stably and safely.

In consideration of the above-described points, it is preferable that the interlayer 28 has a lower resistance value. Specifically, in the piezoelectric film 10 according to the embodiment of the present invention, it is preferable that the resistance value of the laminate of the interlayer 28 and the first electrode layer 14 is 12Ω or less.

It is preferable that the resistance value of the laminate of the interlayer 28 and the first electrode layer 14 is set to 12Ω or less from the viewpoint that the heat generation of the first electrode layer 14 can be more suitably suppressed, a safer wearable speaker can be realized, and the device serving as a vibration plate in a case of using the piezoelectric film 10 according to the embodiment of the present invention as an exciter can be driven more stably and safely.

The resistance value of the laminate of the interlayer 28 and the first electrode layer 14 is more preferably 5Ω or less, still more preferably 3Ω or less, particularly preferably 1.5Ω or less, and most preferably 1.0Ω or less.

Further, it is basically preferable that the resistance value of the laminate of the interlayer 28 and the first electrode layer 14 decreases, but it is unrealistic and difficult to set the resistance value to substantially zero in terms of the cost. In consideration of the above-described point, the resistance value of the laminate of the interlayer 28 and the first electrode layer 14 is preferably 0.1Ω or greater.

Further, in the piezoelectric film 10 according to the embodiment of the present invention, the resistance value (electric resistance value) of the laminate of the interlayer 28 and the first electrode layer 14 may be measured by the following method.

First, in the piezoelectric film 10 to be measured, a through-hole having a diameter of 5 mm is formed at an optional position of the first protective layer 18 which is a protective layer on a side where the interlayer 28 is formed. The through-hole may be formed by a known method depending on the material for forming the first protective layer 18.

Further, a through-hole having a diameter of 5 mm similar to the above-described through-hole is formed at a position spaced by 3 cm from the through-hole formed before the first protective layer 18. Further, the distance between the through-holes is a distance between the centers.

The resistance value between the two points of the first electrode layer 14 exposed as described above and spaced from each other by 3 cm is measured, for example, with an LCR meter. In the piezoelectric film 10 according to the embodiment of the present invention, the resistance value is measured at optionally selected ten sites, and the average value of the measured values is defined as the resistance value of the laminate of the interlayer 28 and the first electrode layer 14.

In the piezoelectric film 10 according to the embodiment of the present invention, in a case where the thickness of the interlayer 28 is identical, the resistance value decreases as the metal atom concentration or the carbon atom concentration increases. Further, in a case where the metal atom concentration or the carbon atom concentration of the interlayer 28 is identical, the resistance value decreases as the thickness of the interlayer 28 increases.

Further, in a case where the forming material is identical, the resistance value decreases as the thickness of the electrode layer increases.

In consideration of the above-described points, in the piezoelectric film 10 according to the embodiment of the present invention, the resistance value of the laminate of the interlayer 28 and the first electrode layer 14 can be adjusted to a desired value by appropriately adjusting one or more of the thickness of the first electrode layer 14, the thickness of the interlayer 28, and the metal or carbon atom concentration of the interlayer 28. Such an interlayer 28 can be formed by various known methods.

The interlayer 28 containing metal atoms is, for example, formed by a method of forming the interlayer 28 using an interlayer solution prepared by dissolving a metal salt such as silver nitrate, a reducing agent such as hexadecanediol, and a compound that is the above-described bonding agent in a solvent and stifling the solution. In this method, the metal atom concentration in the interlayer 28 can be adjusted by adjusting the concentration of the metal salt in the interlayer solution.

As another method, a method of forming the interlayer 28 by using an interlayer solution prepared by adding metal particles to a solution in which a compound that is the above-described bonding agent is dissolved in a solvent, and stifling and dispersing the solution is exemplified. Alternatively, a method of forming the interlayer 28 using a conductive bonding agent having a desired metal atom concentration, prepared by appropriately adding metal particles to a commercially available conductive bonding agent containing metal particles and the like can also be used. In this case, the average primary particle diameter of the metal particles is not limited, but is preferably in a range of 1 to 5000 nm.

Examples of a method of forming the interlayer containing carbon particles include a method of forming the interlayer 28 using an interlayer solution prepared by adding carbon particles such as carbon black to a solution in which a compound that is the above-described bonding agent is dissolved in a solvent, and stifling and dispersing the solution. In this case, the average primary particle diameter of the carbon particles such as carbon black is not limited, but is preferably in a range of 1 to 5000 nm. The piezoelectric film 10 of the illustrated example is formed such that the interlayer 28 is provided between the piezoelectric layer 12 and the first electrode layer 14, that is, only one side between the piezoelectric layer and the electrode layers, but the present invention is not limited thereto.

That is, the piezoelectric film 10 according to the embodiment of the present invention may be formed such that the interlayer 28 is provided both sides between the piezoelectric layer 12 and the first electrode layer 14 and between the piezoelectric layer 12 and the second electrode layer 16.

However, according to a production method illustrated in FIGS. 2 to 5 described below, the bonding force between the piezoelectric layer 12 and the second electrode layer 16 coated with the coating material formed into the piezoelectric layer 12 in the formation of the piezoelectric layer 12 is sufficient. That is, basically, it is not necessary to provide the interlayer 28 on the electrode layer side.

Further, as described above, the provision of the interlayer 28 is advantageous in terms of the resistance value of the electrode layer while it is advantageous that the number of the interlayers 28 is set to 1 in terms of a decrease in film thickness of the piezoelectric film 10, the flexibility, and the like.

Therefore, in consideration of the balance between the suppression of heat generation, the thickness, and the flexibility of the piezoelectric film 10, the interlayer 28 may be formed only on the electrode layer side laminated on the piezoelectric layer 12 after the formation of the piezoelectric layer 12. That is, in the production method illustrated in FIGS. 2 to 5 described later, the interlayer 28 may be provided only between the first electrode layer 14 and the piezoelectric layer 12 as illustrated in FIG. 1.

As described above, the piezoelectric film 10 has a configuration in which the piezoelectric layer 12 containing the piezoelectric particles 26 in the matrix 24 containing the polymer material is sandwiched between the first electrode layer 14 and the second electrode layer 16 and this laminate is sandwiched between the first protective layer 18 and the second protective layer 20. Further, the interlayer 28 is provided between the first electrode layer 14 and the piezoelectric layer 12.

It is preferable that, in such a piezoelectric film 10 according to the embodiment of the present invention, the maximal value of the loss tangent (tanδ) at a frequency of 1 Hz according to dynamic viscoelasticity measurement is present at room temperature and more preferable that the maximal value at which the loss tangent is 0.1 or greater is present at room temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

Further, in the piezoelectric film 10 according to the embodiment of the present invention, it is preferable that the storage elastic modulus (E′) at a frequency of 1 Hz according to the dynamic viscoelasticity measurement is in a range of 10 to 30 GPa at 0° C. and in a range of 1 to 10 GPa at 50° C.

In this manner, the piezoelectric film 10 may have large frequency dispersion in the storage elastic modulus (E′) at room temperature. That is, the piezoelectric film 10 can exhibit a behavior of being rigid with respect to a vibration of 20 Hz to 20 kHz and being flexible with respect to a vibration of less than or equal to a few Hz.

Further, in the piezoelectric film 10 according to the embodiment of the present invention, it is preferable that the product of the thickness and the storage elastic modulus (E′) at a frequency of 1 Hz according to the dynamic viscoelasticity measurement is in a range of 1.0×10⁶ to 2.0×10⁶ N/m at 0° C. and in a range of 1.0×10⁵ to 1.0×10⁶ N/m at 50° C.

In this manner, the piezoelectric film 10 may have moderate rigidity and mechanical strength within a range not impairing the flexibility and the acoustic characteristics.

Further, in the piezoelectric film 10, it is preferable that the loss tangent (Tanδ) at a frequency of 1 kHz at 25° C. is 0.05 or greater in a master curve obtained from the dynamic viscoelasticity measurement.

In this manner, the frequency of a speaker formed of the piezoelectric film 10 is smooth as the frequency characteristic thereof, and thus an amount of a change in acoustic quality in a case where the lowest resonance frequency f₀ is changed according to a change in the curvature of the speaker can be decreased.

Further, the piezoelectric film 10 according to the embodiment of the present invention may further include an electrode lead-out portion that leads out the electrodes from the first electrode layer 14 and the second electrode layer 16, and an insulating layer which covers a region where the piezoelectric layer 12 is exposed for preventing a short circuit or the like, in addition to the above-described layers.

A method of leading out electrodes from the first electrode layer 14 and the second electrode layer 16 is not limited, and various known methods can be used.

Examples thereof include a method of providing portions in the electrode layer and the protective layer, which protrude to the outside of the piezoelectric layer 12 in the plane direction, and leading-out electrodes to the outside from these portions, a method of connecting a conductor such as a copper foil to the first electrode layer 14 and the second electrode layer 16 and leading-out the electrodes to the outside, and a method of forming through-holes in the first protective layer 18 and the second protective layer 20 with a laser or the like, filling the through-holes with a conductive material, and leading-out electrodes to the outside.

As a suitable method of leading out an electrode, the method described in JP2014-209724A, the method described in JP2016-015354A, and the like are exemplified.

Further, the number of electrode lead-out portions is not limited to one, and each electrode layer may have two or more electrode lead-out portions. Particularly in a case of the configuration in which the electrode lead-out portion is obtained by removing a part of the protective layer and inserting a conductive material into the hole portion, it is preferable that the piezoelectric film has three or more electrode lead-out portions in order to more reliably ensure the conduction.

Next, an example of the method of producing the piezoelectric film 10 illustrated in FIG. 1 will be described with reference to the conceptual views of FIGS. 2 to 5.

First, as illustrated in FIG. 2, a sheet-like material 34 in which the second electrode layer 16 is formed on the second protective layer 20 is prepared. The sheet-like material 34 may be prepared by forming a copper thin film or the like as the second electrode layer 16 on the surface of the second protective layer 20 by carrying out vacuum vapor deposition, sputtering, plating, or the like.

In a case where the second protective layer 20 is extremely thin and thus the handleability is degraded, the second protective layer 20 with a separator (temporary support) may be used as necessary. Further, a PET having a thickness of 25 to 100 μm or the like can be used as the separator. The separator may be removed after thermal compression bonding of the second electrode layer 16 and the second protective layer 20 and before lamination of any member on the second protective layer 20.

Meanwhile, the coating material is prepared by dissolving a polymer material having a viscoelasticity at room temperature, such as cyanoethylated PVA, in an organic solvent, adding the piezoelectric particles 26 thereto, and stirring the solution for dispersion.

The organic solvent is not limited, and various organic solvents such as dimethylformamide (DMF), methyl ethyl ketone, and cyclohexanone can be used.

In a case where the sheet-like material 34 is prepared and the coating material is prepared, the coating material is cast (applied) onto the second electrode layer 16 of the sheet-like material 34, and the organic solvent is evaporated and dried. In this manner, as illustrated in FIG. 3, a laminate 36 in which the second electrode layer 16 is provided on the second protective layer 20 and the piezoelectric layer 12 is formed on the second electrode layer 16 is prepared.

A casting method for the coating material is not particularly limited, and all known coating methods (coating devices) such as a slide coater and a doctor knife can be used.

Further, in a case where the viscoelastic material is a material that can be heated and melted, such as cyanoethylated PVA, the laminate 36 in which the first electrode layer 14 is provided on the first protective layer 18 and the piezoelectric layer 12 is formed on the first electrode layer 14 as illustrated in FIG. 3 may be prepared by heating and melting the viscoelastic material to prepare a melt obtained by adding the piezoelectric particles 26 to the melt to be dispersed therein, extruding the melt on the sheet-like material 34 illustrated in FIG. 2 in a sheet shape by carrying out extrusion molding or the like, and cooling the laminate.

As described above, in the piezoelectric film 10, in addition to the viscoelastic material such as cyanoethylated PVA, a dielectric polymer material such as polyvinylidene fluoride may be added to the matrix 24.

In a case where the polymer piezoelectric material is added to the matrix 24, the polymer piezoelectric material to be added to the coating material may be dissolved. Alternatively, the polymer piezoelectric material to be added may be added to the heated and melted viscoelastic material so that the polymer piezoelectric material is heated and melted.

After the preparation of the laminate 36, it is preferable that the surface of the piezoelectric layer 12 is subjected to a calender treatment of pressing the surface using a heating roller or the like for the purpose of flattening the surface of the piezoelectric layer 12, adjusting the thickness of the piezoelectric layer 12, improving the density of the piezoelectric particles 26 in the piezoelectric layer 12, and the like.

The method of performing the calender treatment is not limited, and the calender treatment may be performed by a known method such as pressing the surface with a heating roller described above or a treatment with a pressing machine.

Further, the calender treatment may be performed after the polarization treatment described below. However, in a case where the calender treatment is performed after the polarization treatment is performed, the piezoelectric particles 26 pushed in by the pressure rotate, and the effect of the polarization treatment may decrease. In consideration of this point, it is preferable that the calender treatment is performed before the polarization treatment.

After preparation of the laminate 36 which includes the first electrode layer 14 on the first protective layer 18 and the piezoelectric layer 12 formed on the first electrode layer 14, it is preferable that the polarization treatment (poling) is performed on the piezoelectric layer 12 after the calender treatment is performed on the piezoelectric layer 12.

A method of performing the polarization treatment on the piezoelectric layer 12 is not limited, and a known method can be used. For example, electric field poling treatment in which a DC electric field is directly applied to a target to be subjected to the polarization treatment is exemplified. Further, in a case of performing electric field poling treatment, the electric field poling treatment may be performed using the first electrode layer 14 and the second electrode layer 16 by forming the first electrode layer 14 before the polarization treatment.

Further, in a case where the piezoelectric film 10 according to the embodiment of the present invention is produced, it is preferable that the polarization treatment is performed in the thickness direction of the piezoelectric layer 12 instead of the plane direction.

Meanwhile, a sheet-like material 38 in which the first electrode layer 14 is formed on the first protective layer 18 is prepared. The sheet-like material 38 may be prepared by forming a copper thin film or the like as the first electrode layer 14 on the surface of the first protective layer 18 using vacuum vapor deposition, sputtering, plating, or the like. That is, the sheet-like material 38 may be the same as the sheet-like material 34 described above.

In addition, as described above, an interlayer solution for forming the interlayer 28 containing a metal is prepared, for example, by dissolving a metal salt such as copper nitrate, a reducing agent such as hexadecanediol, and a compound serving as the bonding agent in a solvent and stirring the solution. Alternatively, an interlayer solution for forming the interlayer 28 containing carbon particles is prepared by adding carbon particles such as carbon black to a solution in which a compound serving as the bonding agent is dissolved in a solvent, and stirring and dispersing the solution.

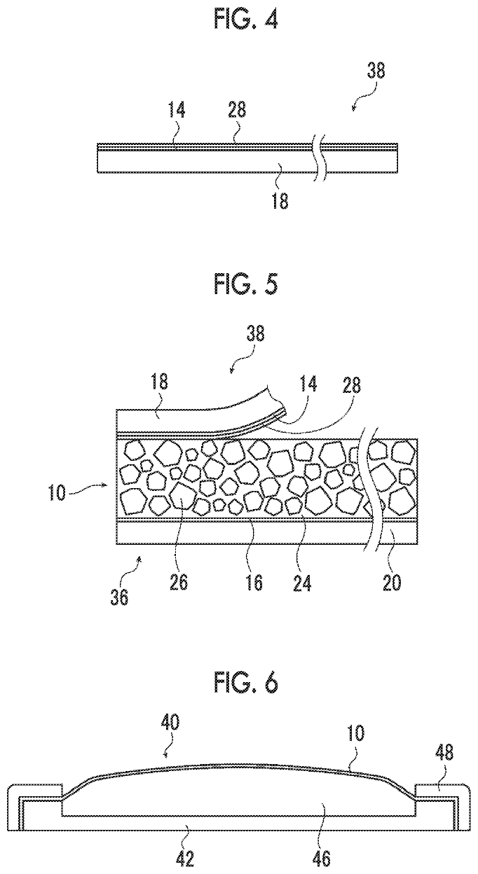

Next, the first electrode layer 14 of the sheet-like material 38 is coated with the prepared interlayer solution and dried to form the interlayer 28 on the surface of the first electrode layer 14 as illustrated in FIG. 4.

A method of coating the first electrode layer with the interlayer solution is not limited, and various known methods can be used.

Next, as illustrated in FIG. 5, the sheet-like material 38 including the interlayer 28 is laminated on the laminate 36 in a state where the interlayer 28 (first electrode layer 14) faces the piezoelectric layer 12.

Further, a laminate of the laminate 36 and the sheet-like material 38 including the interlayer 28 is subjected to the thermal compression bonding using a heating press device, a heating roller pair, or the like such that the second protective layer 20 and the first protective layer 18 are sandwiched between the laminate 36 and the sheet-like material 38, thereby preparing the piezoelectric film 10.

The piezoelectric film 10 to be prepared in the above-described manner is polarized in the thickness direction instead of the plane direction, and thus excellent piezoelectric characteristics are obtained even in a case where the stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

Further, the piezoelectric film 10 may be produced using the cut sheet-like material 34 and the cut sheet-like material 38 or may be produced using Roll to Roll.

FIG. 5 conceptually illustrates an example of a flat plate type piezoelectric speaker formed of the piezoelectric film 10 according to the embodiment of the present invention.

The piezoelectric speaker 40 is a flat plate type piezoelectric speaker formed of the piezoelectric film 10 as a vibration plate that converts an electrical signal into vibration energy. Further, the piezoelectric speaker 40 can also be used as a microphone, a sensor, or the like. Further, this piezoelectric speaker can also be used as a vibration sensor.

The piezoelectric speaker 40 is configured to have the piezoelectric film 10, a case 42, a viscoelastic support 46, and a frame 48.

The case 42 is a thin housing formed of plastic or the like and having one surface that is open. Examples of the shape of the housing include a rectangular parallelepiped shape, a cubic shape, and a cylindrical shape.

Further, the frame 48 is a frame material that has, in the center thereof, a through-hole having the same shape as the open surface of the case 42 and engages with the open surface side of the case 42.

The viscoelastic support 46 is a support used for efficiently converting the stretch and contraction movement of the piezoelectric film 10 into a forward and rearward movement (a movement in the direction perpendicular to the surface of the film) by means of having moderate viscosity and elasticity, supporting the piezoelectric film 10, and applying a constant mechanical bias to any place of the piezoelectric film. Examples of the viscoelastic support include wool felt, nonwoven fabric such as wool felt containing PET, and glass wool.

The piezoelectric speaker 40 is configured by accommodating the viscoelastic support 46 in the case 42, covering the case 42 and the viscoelastic support 46 with the piezoelectric film 10, and fixing the frame 48 to the case 42 in a state of pressing the periphery of the piezoelectric film 10 against the upper end surface of the case 42 by the frame 48.

Here, in the piezoelectric speaker 40, the viscoelastic support 46 has a shape in which the height (thickness) is larger than the height of the inner surface of the case 42.

Therefore, in the piezoelectric speaker 40, the viscoelastic support 46 is held in a state of being thinned by being pressed downward by the piezoelectric film 10 at the peripheral portion of the viscoelastic support 46. Similarly, in the peripheral portion of the viscoelastic support 46, the curvature of the piezoelectric film 10 suddenly fluctuates, and a rising portion that decreases in height toward the periphery of the viscoelastic support 46 is formed in the piezoelectric film 10. Further, the central region of the piezoelectric film 10 is pressed by the viscoelastic support 46 having a square columnar shape and has a (approximately) planar shape.

In the piezoelectric speaker 40, in a case where the piezoelectric film 10 is stretched in the plane direction due to the application of a driving voltage to the first electrode layer 14 and the second electrode layer 16, the rising portion of the piezoelectric film 10 changes the angle in a rising direction due to the action of the viscoelastic support 46 in order to absorb the stretched part. As a result, the piezoelectric film 10 having the planar portion moves upward.

On the contrary, in a case where the piezoelectric film 10 is contracted in the plane direction due to the application of the driving voltage to the second electrode layer 16 and the first electrode layer 14, the rising portion of the piezoelectric film 10 changes the angle in a falling direction (a direction approaching the flat surface) in order to absorb the contracted part. As a result, the piezoelectric film 10 having the planar portion moves downward.

The piezoelectric speaker 40 generates a sound by the vibration of the piezoelectric film 10.

In the piezoelectric film 10 according to the embodiment of the present invention, the conversion from the stretching and contracting movement to vibration can also be achieved by holding the piezoelectric film 10 in a bent state.

Therefore, the piezoelectric film 10 according to the embodiment of the present invention can function as a piezoelectric speaker having flexibility, a vibration sensor, or the like by being simply maintained in a bent state instead of the flat plate-like piezoelectric speaker 40 having rigidity as illustrated in FIG. 6.

The piezoelectric speaker formed of the piezoelectric film 10 can be stored in a bag or the like by, for example, being rolled or folded using the satisfactory flexibility. Therefore, with the piezoelectric film 10, a piezoelectric speaker that can be easily carried even in a case where the piezoelectric speaker has a certain size can be realized.

Further, as described above, the piezoelectric film 10 has excellent elasticity and excellent flexibility, and has no in-plane anisotropy as a piezoelectric characteristic. Therefore, in the piezoelectric film 10, a change in acoustic quality regardless of the direction in which the film is bent is small, and a change in acoustic quality with respect to the change in curvature is also small. Accordingly, the piezoelectric speaker formed of the piezoelectric film 10 has a high degree of freedom of the installation place and can be attached to various products as described above. For example, a so-called wearable speaker can be realized by mounting the piezoelectric film 10 on clothing such as a suit and portable items such as a bag in a bent state.

Further, as described above, the piezoelectric film according to the embodiment of the present invention can be used as a speaker of a display device by bonding the piezoelectric film to a display device having flexibility such as an organic electroluminescence display having flexibility or a liquid crystal display having flexibility.

As described above, the piezoelectric film 10 stretches and contracts in the plane direction in a case where a voltage is applied, and vibrates suitably in the thickness direction due to the stretch and contraction in the plane direction, and thus a satisfactory acoustic characteristic of outputting a sound with a high sound pressure is exhibited in a case where the piezoelectric film 10 is used as a piezoelectric speaker or the like.

The piezoelectric film 10, which exhibits satisfactory acoustic characteristics, that is, high stretch and contraction performance due to piezoelectricity satisfactorily acts as a piezoelectric vibrating element that vibrates a vibration body such as a vibration plate by laminating a plurality of layers of the piezoelectric films 10 to obtain a laminated piezoelectric element.

As described above, since the piezoelectric film 10 according to the embodiment of the present invention includes the interlayer, the heat generation of the first electrode layer 14 can be suppressed, and the heat radiation property is enhanced. Therefore, the piezoelectric film 10 according to the embodiment of the present invention suppresses heat generation and radiates heat even in a case where a piezoelectric vibrating element is formed by laminating the piezoelectric films, and thus the vibration plate can be prevented from being heated.

Further, in a case of lamination of the piezoelectric films 10, each piezoelectric film may not have the first protective layer 18 and/or the second protective layer 20 unless there is a possibility of a short circuit. Alternatively, the piezoelectric films that do not have the first protective layer 18 and/or the second protective layer 20 may be laminated through an insulating layer.

As an example, the laminated piezoelectric element obtained by laminating the piezoelectric films 10 is bonded to a vibration plate and may be used as a speaker which outputs a sound by vibrating the vibration plate using the laminate of the piezoelectric films 10. That is, in this case, the laminate of the piezoelectric films 10 acts as a so-called exciter that outputs a sound by vibrating the vibration plate.

By applying a driving voltage to the laminated piezoelectric element obtained by laminating the piezoelectric films 10, each of the piezoelectric films 10 stretches and contracts in the plane direction, and the entire laminate of the piezoelectric films 10 stretches and contracts in the plane direction due to the stretch and contraction of each of the piezoelectric films 10. The vibration plate to which the laminate has been bonded is bent due to the stretch and contraction of the laminated piezoelectric element in the plane direction, and as a result, the vibration plate vibrates in the thickness direction. The vibration plate generates a sound using the vibration in the thickness direction. The vibration plate vibrates according to the magnitude of the driving voltage applied to the piezoelectric film 10 and generates a sound according to the driving voltage applied to the piezoelectric film 10.

Therefore, the piezoelectric film 10 itself does not output sound in this case.

Therefore, even in a case where the rigidity of each piezoelectric film 10 is low and the stretching and contracting force thereof is small, the rigidity of the laminated piezoelectric element obtained by laminating the piezoelectric films 10 is increased, and the stretching and contracting force as the entire laminate is increased. As a result, in the laminated piezoelectric element obtained by laminating the piezoelectric films 10, even in a case where the vibration plate has a certain degree of rigidity, the vibration plate is sufficiently bent with a large force and can be sufficiently vibrated in the thickness direction, and thus the vibration plate can generate a sound.

In the laminated piezoelectric element obtained by laminating the piezoelectric films the number of laminated sheets of the piezoelectric films 10 is not limited, and the number of sheets set such that a sufficient amount of vibration is obtained may be appropriately set according to, for example, the rigidity of the vibration plate to be vibrated.

Further, one piezoelectric film 10 can also be used as a similar exciter (piezoelectric vibrating element) in a case where the piezoelectric film 10 has a sufficient stretching and contracting force.

The vibration plate that is vibrated by the laminated piezoelectric element obtained by laminating the piezoelectric films 10 is not limited, and various sheet-like materials (plate-like materials and films) can be used.

Examples thereof include a resin film consisting of polyethylene terephthalate (PET) and the like, foamed plastic consisting of foamed polystyrene and the like, a paper material such as a corrugated cardboard material, a glass plate, and wood. Further, various machines (devices) such as display devices such as an organic electroluminescence display and a liquid crystal display may be used as the vibration plate as long as the devices can be sufficiently bent.

It is preferable that the laminated piezoelectric element obtained by laminating the piezoelectric films 10 is formed by bonding the adjacent piezoelectric films 10 with a bonding layer (bonding agent). Further, it is preferable that the laminated piezoelectric element and the vibration plate are also bonded with a bonding layer.

The bonding layer is not limited, and various layers that can bond materials to be bonded can be used. Therefore, the bonding layer may consist of a pressure sensitive adhesive or an adhesive. It is preferable that an adhesive layer consisting of an adhesive is used from the viewpoint that a solid and hard bonding layer is obtained after the bonding.

The same applies to the laminate formed by folding back the long piezoelectric film described later.

In the laminated piezoelectric element obtained by laminating the piezoelectric films the polarization direction of each piezoelectric film 10 to be laminated is not limited. As described above, it is preferable that the piezoelectric film 10 according to the embodiment of the present invention is polarized in the thickness direction. Accordingly, the polarization direction of the piezoelectric film 10 here is a polarization direction in the thickness direction.

Therefore, in the laminated piezoelectric element, the polarization directions may be the same for all the piezoelectric films 10, and piezoelectric films having different polarization directions may be present.

In a laminated piezoelectric element obtained by laminating the piezoelectric films 10, it is preferable that the piezoelectric films 10 are laminated such that the adjacent piezoelectric films 10 have polarization directions opposite to each other.

In the piezoelectric film 10, the polarity of the voltage to be applied to the piezoelectric layer 12 depends on the polarization direction of the piezoelectric layer 12. Therefore, even in a case where the polarization direction is directed from the first electrode layer 14 toward the second electrode layer 16 or from the second electrode layer 16 toward the first electrode layer 14, the polarity of the first electrode layer 14 and the polarity of the second electrode layer 16 in all the piezoelectric films 10 to be laminated are set to be the same as each other.

Therefore, by reversing the polarization directions of the adjacent piezoelectric films 10, even in a case where the electrode layers of the adjacent piezoelectric films 10 come into contact with each other, the electrode layers in contact with each other have the same polarity, and thus there is no risk of a short circuit.

The laminated piezoelectric element obtained by laminating the piezoelectric films 10 may have a configuration in which a plurality of piezoelectric films 10 are laminated by folding the piezoelectric film 10 once or more times, preferably a plurality of times.

The configuration in which the piezoelectric film 10 is folded back and laminated has the following advantages.

That is, in the laminate in which a plurality of cut sheet-like piezoelectric films 10 are laminated, the first electrode layer 14 and the second electrode layer 16 need to be connected to a driving power supply for each piezoelectric film. On the contrary, in the configuration in which the long piezoelectric film 10 is folded back and laminated, only one sheet of the long piezoelectric film 10 can form the laminated piezoelectric element. Further, in the configuration in which the long piezoelectric film 10 is folded back and laminated, only one power source is required for applying the driving voltage, and the electrode may be led out from the piezoelectric film 10 at one site.

Further, in the configuration in which the long piezoelectric film 10 is folded back and laminated, the polarization directions of the adjacent piezoelectric films 10 are inevitably opposite to each other. Further, such a laminated piezoelectric element obtained by providing electrode layers on both surfaces of a piezoelectric layer consisting of a polymer-based piezoelectric composite material and preferably by laminating piezoelectric films in which a protective layer is provided on the surface of an electrode layer is described in WO2020/095812A and WO2020/179353A.

The piezoelectric film and the laminated piezoelectric element according to the embodiment of the present invention are suitably used for various applications, such as various sensors, acoustic devices, haptics, ultrasonic transducers, actuators, damping materials (dampers), and vibration power generation devices.

Specifically, examples of the sensors formed of the piezoelectric film and the laminated piezoelectric element according to the embodiment of the present invention include sound wave sensors, ultrasound sensors, pressure sensors, tactile sensors, strain sensors, and vibration sensors. The sensors formed of the piezoelectric film and the laminated piezoelectric element according to the embodiment of the present invention are particularly useful for infrastructure inspection such as crack detection and inspection at a manufacturing site such as foreign matter contamination detection.

Examples of the acoustic devices formed of the piezoelectric film and the laminated piezoelectric element according to the embodiment of the present invention include microphones, pickups, speakers, and exciters. Specific applications of the acoustic devices formed of the piezoelectric film and the laminated piezoelectric element according to the embodiment of the present invention include noise cancellers used for cars, trains, airplanes, robots, and the like, artificial voice cords, buzzers for preventing invasion of pests and harmful animals, furniture having a voice output function, wallpaper, photos, helmets, goggles, headrests, signage, and robots.

Application examples of the haptics formed of the piezoelectric film and the laminated piezoelectric element according to the embodiment of the present invention include automobiles, smartphones, smart watches, and game machines.

Examples of the ultrasonic transducers formed of the piezoelectric film and the laminated piezoelectric element according to the embodiment of the present invention include ultrasound probes and hydrophones.

Examples of the applications of the actuators formed of the piezoelectric film and the laminated piezoelectric element according to the embodiment of the present invention include water droplet adhesion prevention, transport, stirring, dispersion, and polishing.

Application examples of the damping materials formed of the piezoelectric film and the laminated piezoelectric element according to the embodiment of the present invention include containers, vehicles, buildings, and sports goods such as skis and rackets.

Further, application examples of the vibration power generation devices formed of the piezoelectric film and the laminated piezoelectric element according to the embodiment of the present invention include roads, floors, mattresses, chairs, shoes, tires, wheels, and personal computer keyboards.

Hereinbefore, the piezoelectric film and the laminated piezoelectric element according to the embodiment of the present invention have been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention.

[Preparation of Piezoelectric Film]

A piezoelectric film illustrated in FIG. 1 was prepared by the methods illustrated in FIGS. 2 to 5.

First, cyanoethylated PVA (CR-V, manufactured by Shin-Etsu Chemical Co., Ltd.) was dissolved in dimethylformamide (DMF) at the following compositional ratio. Thereafter, PZT particles serving as the piezoelectric particles were added to the solution at the following compositional ratio, and the solution was stirred using a propeller mixer (rotation speed of 2000 rpm), thereby preparing a paint for forming a piezoelectric layer.
PZT Particles: 300 parts by mass
Cyanoethylated PVA: 30 parts by mass
DMF: 70 parts by mass

Further, PZT particles obtained by sintering mixed powder, formed by wet-mixing powder of a Pb oxide, a Zr oxide, and a Ti oxide as the main components such that the amount of Zr and the amount of Ti respectively reached 0.52 moles and 0.48 moles with respect to 1 mole of Pb using a ball mill, at 800° C. for 5 hours and being subjected to a crushing treatment were used as the PZT particles.

Further, two sheets of sheet-like materials obtained by performing vacuum vapor deposition on a copper thin film having a thickness of 0.1 μm were prepared on a PET film having a thickness of 4 μm. That is, in the present example, the first electrode layer and the second electrode layer are copper vapor deposition thin films having a thickness of 0.1 μm, and the first protective layer and the second protective layer are PET films having a thickness of 4 μm.

The copper thin film (second electrode layer) of one sheet-like material was coated with the coating material for forming the piezoelectric layer prepared in advance using a slide coater. Further, the second electrode layer was coated with the coating material such that the film thickness of the coating film after being dried reached 40 μm.

Next, the material obtained by coating the sheet-like material with the paint was heated and dried on a hot plate at 120° C. to evaporate DMF. In this manner, a laminate in which the second electrode layer made of copper was provided on the second protective layer made of PET and the piezoelectric layer (polymer-based piezoelectric composite material layer) having a thickness of 30 μm was formed thereon was prepared.

The prepared piezoelectric layer was subjected to a calender treatment using a heating roller.

Further, the prepared piezoelectric layer was subjected to a polarization treatment in the thickness direction.

A copper thin film (first electrode layer) of another sheet-like material was coated with the following interlayer solution using a slide coater.

The sheet-like material coated with the interlayer solution was heated and dried at 120° C. using a hot plate to evaporate the solvent, thereby forming an interlayer. In this manner, a sheet-like material in which the PET film, the copper thin film, and the interlayer were laminated was prepared.

Further, the thickness of the interlayer was controlled by adjusting the concentration of solid contents of the interlayer solution described below and the jetting amount.

The sheet-like material in which the PET film, the copper thin film, and the interlayer were laminated was laminated on the laminate formed by performing the polarization treatment on the piezoelectric layer such that the interlayer (first electrode layer (copper thin film)) faced the piezoelectric layer.

Next, a piezoelectric film as illustrated in FIG. 1 was prepared by performing thermal compression bonding on the laminate of the laminate and the sheet-like material at a temperature of 120° C. using a laminator device, and bonding and adhering the piezoelectric layer and the first electrode layer to each other with the interlayer.

[Interlayer Solution]

<Interlayer Solution Containing Platinum>

Platinum acetylacetonate (manufactured by Sigma-Aldrich Co. LLC.), hexadecanediol (manufactured by Sigma-Aldrich Co. LLC.), and cyanoethylated PVA (CR-V, manufactured by Shin-Etsu Chemical Co., Ltd.) were dissolved in dioctyl ether. This solution was heated to 120° C. under white light to prepare an interlayer solution for forming an interlayer containing platinum.

Further, the atomic concentration of platinum in the interlayer was controlled by adjusting the proportions of the platinum acetylacetonate, the hexadecanediol, and the cyanoethylated PVA in the interlayer solution.

<Interlayer Solution Containing Gold>

Tetrachloroauric (III) acid (manufactured by Sigma-Aldrich Co. LLC.), hexadecanediol (manufactured by Sigma-Aldrich Co. LLC.), and cyanoethylated PVA (CR-V, manufactured by Shin-Etsu Chemical Co., Ltd.) were dissolved in dioctyl ether. This solution was stirred under white light to prepare an interlayer solution for forming an interlayer containing gold.

Further, the atomic concentration of gold in the interlayer was controlled by adjusting the proportions of the tetrachloroauric (III) acid, the hexadecanediol, and the cyanoethylated PVA.

<Interlayer Solution Containing Silver>

Silver nitrate (manufactured by Sigma-Aldrich Co. LLC.), hexadecanediol (manufactured by Sigma-Aldrich Co. LLC.), and cyanoethylated PVA (CR-V, manufactured by Shin-Etsu Chemical Co., Ltd.) were dissolved in acetone. This solution was stirred under white light to prepare an interlayer solution for forming an interlayer containing silver.

Further, the atomic concentration of silver in the interlayer was controlled by adjusting the proportions of the silver nitrate, the hexadecanediol, and the cyanoethylated PVA.

<Interlayer Solution Containing Copper>

Copper nitrate (manufactured by Sigma-Aldrich Co. LLC.), hexadecanediol (manufactured by Sigma-Aldrich Co. LLC.), and cyanoethylated PVA (CR-V, manufactured by Shin-Etsu Chemical Co., Ltd.) were dissolved in ethanol. This solution was heated and refluxed at 79° C. under white light to prepare an interlayer solution for forming an interlayer containing copper.

Further, the atomic concentration of copper in the interlayer was controlled by adjusting the proportions of the copper nitrate, the hexadecanediol, and the cyanoethylated PVA.

<Interlayer Solution Containing Nickel>

Tetracarbonyl nickel (manufactured by Sigma-Aldrich Co. LLC.) and cyanoethylated PVA (CR-V, manufactured by Shin-Etsu Chemical Co., Ltd.) were dissolved in dioctyl ether. This solution was heated to 120° C. to prepare an interlayer solution for forming an interlayer containing nickel.

Further, the atomic concentration of nickel in the interlayer was controlled by adjusting the proportions of the tetracarbonyl nickel and the cyanoethylated PVA.

<Interlayer Solution Containing Carbon Particles>

Carbon black (average primary particle diameter of 40 nm), cyanoethylated PVA (CR-V, manufactured by Shin-Etsu Chemical Co., Ltd.), and cyclohexanone were put into a batch-type ultrasonic dispersing device equipped with a stirrer and subjected to a liquefying treatment at a stirring rotation speed of 1500 rpm for 6 hours, thereby preparing a carbon black liquid.

The prepared carbon black liquid was subjected to a dispersion treatment for 6 passes by setting a one pass retention time to 2 minutes with a horizontal beads mill disperser using Zr beads having a particle diameter of 0.5 mm under conditions of a bead filling rate of 80% and a rotor tip peripheral speed of 10 msec.

The liquid was stirred with a dissolver stirrer at a peripheral speed of 10 msec for 30 minutes and treated for 3 passes with a flow-type ultrasonic disperser at a flow rate of 3 kg/min, thereby preparing an interlayer solution for forming an interlayer containing carbon particles.

Further, the atomic concentration of carbon in the interlayer was controlled by adjusting the proportions of the carbon black and the cyanoethylated PVA.

### Examples 1 to 28 and Comparative Examples 2 to 6 and 8

Each piezoelectric film was prepared as described above by variously changing the atomic concentrations of the metal and the carbon and the thickness of the interlayer in the formation of the interlayer formed of each interlayer solution prepared above.

### Comparative Example 1

Platinum was vacuum-deposited on a copper thin film (first electrode layer) of a sheet-like material formed by vacuum-depositing a copper thin film on a PET film, to form a platinum film having a thickness of 1000 nm.

A piezoelectric film was prepared in the same manner as in Example 1 except that the platinum film was used as an interlayer.

### Comparative Example 7

Carbon was vacuum-deposited on a copper thin film (first electrode layer) of a sheet-like material formed by vacuum-depositing a copper thin film on a PET film, to form a carbon film having a thickness of 1000 nm.

A piezoelectric film was prepared in the same manner as in Example 1 except that the carbon film was used as an interlayer.

### Comparative Example 9

A piezoelectric film was prepared in the same manner as in Example 1 except that an interlayer was not formed.

### Comparative Example 10

A cyanoethylated PVA (CR-V, manufactured by Shin-Etsu Chemical Co., Ltd.) was dissolved in dioctyl ether to prepare an interlayer solution.

A piezoelectric film was prepared in the same manner as in Example 1 except that the interlayer solution was used.

[Measurement of Metal Atom Concentration and Carbon Atom Concentration of Interlayer]

A sample was cut out from the prepared piezoelectric film, and the metal atom concentration and the carbon atom concentration of the interlayer were measured by the following method.

First, the piezoelectric film was cut and machined in the thickness direction in order to observe the cross section of the piezoelectric film. The piezoelectric film was machined by mounting a histo knife blade (manufactured by Drukker) having a width of 8 mm on RM2265 (manufactured by Leica Biosystems) and setting the speed to a controller scale of 1 and an engagement amount of 0.25 to 1μm, to expose the cross section.

The cross section was observed with a SEM (for example, S4800, manufactured by Hitachi High-Tech Corporation). The sample was subjected to a conductive treatment by platinum vapor deposition, and the work distance was set to 15 mm. An atomic concentration detector EMAX X-act (manufactured by HORIBA, Ltd.) was inserted into the SEM under conditions of an acceleration voltage of 15 kV, an emission of 10 μA, and a probe current of High. The measurement was performed using EMAX software by capturing an image in “analysis region” of a navigator, selecting “spectrum collection”, and performing collection of point X-rays on the interlayer in the image appearing in the right window. Finally, “quantification” was selected, and the atomic concentration (atom number concentration [atm %]) values of the metal atoms and the carbon atoms of the interlayer were obtained.

Such measurement was carried out at optional positions on optional ten cross sections, and the average value thereof was defined as the metal atom concentration and the carbon atom concentration of the interlayer in the piezoelectric film to be measured.

[Evaluation]

<Preparation of Piezoelectric Speaker and Measurement of Sound Pressure>

The piezoelectric speaker illustrated in FIG. 6 was prepared using the prepared piezoelectric film.

First, a rectangular test piece having a size of 210×300 mm (A4 size) was cut out from the prepared piezoelectric film. The cut-out piezoelectric film was placed on a 210×300 mm case in which glass wool serving as a viscoelastic support was stored in advance as illustrated in FIG. 6, and the peripheral portion was pressed by a frame to impart an appropriate tension and an appropriate curvature to the piezoelectric film, thereby preparing a piezoelectric speaker as illustrated in FIG. 6.

The depth of the case was set to 9 mm, the density of glass wool was set to 32 kg/m³, and the thickness before assembly was set to 25 mm.

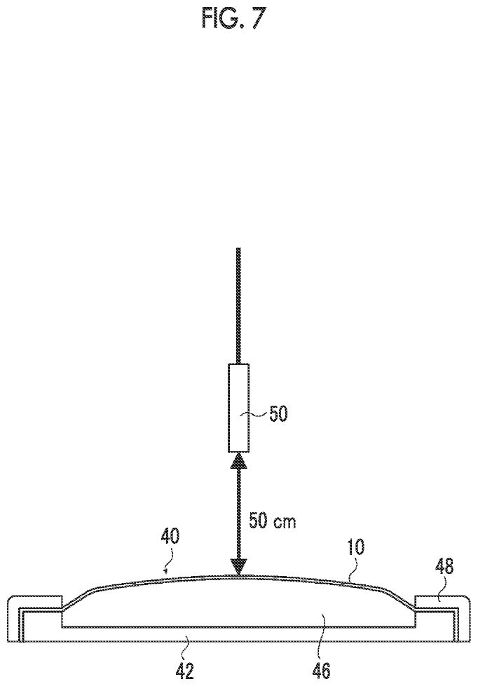

A 1 kHz sine wave was input to the prepared piezoelectric speaker as an input signal through a power amplifier, and the sound pressure was measured with a microphone 50 placed at a distance of 50 cm from the center of the speaker as conceptually illustrated in FIG. 7.

The sound pressure was measured twice, 30 seconds after the start of the output from the piezoelectric speaker (initial) and 126 hours after the start of the output from the piezoelectric speaker (after the durability test). The sound pressures at the initial stage and after the durability test (after durability), and the difference (difference)between the sound pressure at the initial stage and the sound pressure after the durability test are listed in Table 1.

<Resistance Value>

A through-hole having a diameter of 5 mm was formed in the first protective layer of the prepared piezoelectric film using a carbon dioxide gas laser. Next, a through-hole having a diameter of 5 mm was formed at a position separated by a distance of 3 cm from the through-hole formed in the first protective layer. The distance between the through-holes is the distance between the centers.

The resistance value of the laminate of the interlayer and the electrode layer of the piezoelectric film was measured by bringing each probe of an LCR meter into contact with the electrode layer exposed by the formation of the through-hole.

<Heat Generation>

A duplex thermocouple (K type, manufactured by Three High Co., Ltd.) was attached to the surface of the prepared piezoelectric film using black tape (manufactured by TASCO) having a size of 2 cm×2 cm and a thickness of 0.1 mm.

An SN1 signal having a voltage of 50 Vrms was input as an input signal to the prepared piezoelectric film in an environment of an ambient temperature of 24±1° C. and a relative humidity of 50±5% through a power amplifier, and the temperature of the piezoelectric film was measured by the attached thermocouple. Further, the temperature was measured in a state where the piezoelectric film was floated in the air. The temperature at a time point at which the temperature rise was saturated after the input of the SN1 signal was defined as the heat generation temperature (heat generation).

The above-described results are also collectively listed in Table 1.

TABLE 1

| | Interlayer | | | | Evaluation | | | | |
|---|---|---|---|---|---|---|---|---|---|
| | | | Atomic concentration | | Sound pressure [db] | | | | Heat |
| | Thickness | Conductive | [atm %] | | | After | | Resistance | generation |
| | [nm] | material | Metal | Carbon | Initial stage | durability | Difference | value [Ω] | [° C.] |
| Example 1 | 1000 | Platinum | 90 | 7.5 | 79 | 74 | −5 | 0.6 | 37 |
| Example 2 | 1000 | | 60 | 30 | 77 | 75 | −2 | 0.8 | 43 |
| Example 3 | 1000 | | 30 | 52.5 | 62 | 60 | −2 | 1 | 47 |
| Example 4 | 1000 | Gold | 90 | 7.5 | 78 | 74 | −4 | 0.6 | 37 |
| Example 5 | 1000 | | 60 | 30 | 77 | 74 | −3 | 0.8 | 43 |
| Example 6 | 1000 | | 30 | 52.5 | 62 | 60 | −2 | 1 | 47 |
| Example 7 | 1000 | Silver | 90 | 7.5 | 78 | 74 | −4 | 0.6 | 37 |
| Example 8 | 1000 | | 60 | 30 | 77 | 74 | −3 | 0.8 | 43 |
| Example 9 | 1000 | | 30 | 52.5 | 62 | 60 | −2 | 1 | 47 |
| Example 10 | 1000 | Copper | 90 | 7.5 | 78 | 73 | −5 | 0.6 | 37 |
| Example 11 | 1000 | | 60 | 30 | 77 | 74 | −3 | 0.8 | 43 |
| Example 12 | 1000 | | 30 | 52.5 | 62 | 60 | −2 | 1 | 47 |
| Example 13 | 1000 | Nickel | 90 | 7.5 | 78 | 73 | −5 | 0.6 | 37 |
| Example 14 | 1000 | | 60 | 30 | 77 | 74 | −3 | 0.8 | 43 |
| Example 15 | 1000 | | 30 | 52.5 | 62 | 60 | −2 | 1 | 47 |
| Example 16 | 1000 | Carbon | 0 | 95 | 78 | 72 | −6 | 0.6 | 37 |
| Example 17 | 1000 | | 0 | 90 | 75 | 71 | −4 | 0.8 | 43 |
| Example 18 | 1000 | | 0 | 85 | 55 | 51 | −4 | 1 | 47 |
| Example 19 | 5500 | Nickel | 60 | 30 | 53 | 51 | −2 | 0.4 | 35 |
| Example 20 | 5000 | | 60 | 30 | 55 | 53 | −2 | 0.5 | 37 |
| Example 21 | 200 | | 60 | 30 | 79 | 72 | −7 | 1 | 47 |
| Example 22 | 5 | | 60 | 30 | 80 | 71 | −9 | 1.1 | 48 |
| Example 23 | 3 | | 60 | 30 | 80 | 70 | −10 | 1.4 | 51 |
| Example 24 | 5500 | Carbon | 0 | 90 | 53 | 51 | −2 | 0.4 | 35 |
| Example 25 | 5000 | | 0 | 90 | 56 | 54 | −2 | 0.5 | 37 |
| Example 26 | 200 | | 0 | 90 | 79 | 72 | −7 | 1 | 47 |
| Example 27 | 5 | | 0 | 90 | 80 | 71 | −9 | 1.2 | 49 |
| Example 28 | 3 | | 0 | 90 | 80 | 70 | −10 | 1.4 | 51 |
| Comparative | 1000 | Platinum | 100 | 0 | 78 | 65 | −13 | 0.5 | 35 |
| Example 1 | | | | | | | | | |
| Comparative | 1000 | | 20 | 60 | 45 | 43 | −2 | 1.4 | 51 |
| Example 2 | | | | | | | | | |
| Comparative | 1000 | Gold | 20 | 60 | 45 | 42 | −3 | 1.5 | 51 |
| Example 3 | | | | | | | | | |
| Comparative | 1000 | Silver | 20 | 60 | 46 | 43 | −3 | 1.4 | 51 |
| Example 4 | | | | | | | | | |
| Comparative | 1000 | Copper | 20 | 60 | 45 | 42 | −3 | 1.5 | 51 |
| Example 5 | | | | | | | | | |
| Comparative | 1000 | Nickel | 20 | 60 | 45 | 43 | −2 | 1.4 | 51 |
| Example 6 | | | | | | | | | |
| Comparative | 1000 | Carbon | 0 | 100 | 78 | 65 | −13 | 0.5 | 35 |
| Example 7 | | | | | | | | | |
| Comparative | 1000 | | 0 | 80 | 40 | 37 | −3 | 1.4 | 52 |
| Example 8 | | | | | | | | | |
| Comparative | 0 | — | — | — | 82 | 70 | −12 | 1.6 | 54 |
| Example 9 | | | | | | | | | |
| Comparative | 1000 | — | 0 | 75 | 40 | 37 | −3 | 1.4 | 52 |
| Example 10 | | | | | | | | | |

As listed in the table, in all the piezoelectric films of the present invention, including an interlayer and satisfying a metal atom concentration of 30 to 90 atm % or a carbon atom concentration of 85 to 95 atm % in the interlayer, the initial sound pressure was 50 dB or greater, and a decrease in sound pressure even after the durability test (after durability) was 12 dB or less, which was small. In addition, in the piezoelectric films of the present invention, the resistance value of the laminate of the interlayer and the first electrode layer was 1.4Ω or less, which was small, and the heat generation was suppressed to 51° C. or lower.

In addition, as shown in Examples 19 to 23 and 24 to 28, the initial sound pressure was increased to 55 dB or greater and the decrease in sound pressure after the durability test was suppressed to less than 10 dB by setting the thickness of the interlayer to be in a range of 5 to 5000 nm. In addition, the heat generation can be set to lower than 50° C. by setting the resistance value of the laminate of the interlayer and the first electrode layer to 12Ω or less.

On the contrary, in Comparative Example 1 in which the interlayer was formed only of platinum and Comparative Example 7 in which the interlayer was formed only of carbon, the initial sound pressure was high and the resistance value (heat generation) was low, but the piezoelectric layer and the first electrode layer were considered to be peeled off due to the durability test, and the decrease in sound pressure after the durability test was 13 dB, which was large.

Further, in Comparative Examples 2 to 6 and Comparative Example 8 in which the metal atom concentration of the interlayer was less than 30 atm % and the carbon atom concentration of the interlayer was less than 85 atm %, the initial sound pressure was 50 dB or less, which was low.

Further, in Comparative Example 9 in which the interlayer was not provided, the resistance value was 1.6Ω, which was large, and the heat generation was also high.

Further, in Comparative Example 10 in which the interlayer did not contain the metal and the carbon particles, the initial sound pressure was 50 dB or less, which was low.

As shown in the results described above, the effects of the present invention are apparent.

The present invention can be suitably used for electroacoustic transducers such as speakers, vibration sensors, and the like.

### EXPLANATION OF REFERENCES

10: piezoelectric film

12: piezoelectric layer

14: first electrode layer

16: second electrode layer

18: first protective layer

20: second protective layer

24: matrix

26: piezoelectric particle

28: interlayer

34, 38: sheet-like material

36: laminate

40: piezoelectric speaker

42: case

46: viscoelastic support

48: frame

50: microphone

What is claimed is:

1. A piezoelectric film comprising:
a piezoelectric layer containing piezoelectric particles in a matrix that contains a polymer material;
electrode layers provided on both surfaces of the piezoelectric layer; and
an interlayer provided on at least one side between the piezoelectric layer and the electrode layers,
wherein the interlayer contains carbon and/or a metal, and
any of a metal atom concentration of 30 to 90 atm % or a carbon atom concentration of 85 to 95 atm % is satisfied.

2. The piezoelectric film according to claim 1,
wherein the interlayer has a thickness of 5 to 5000 nm.

3. The piezoelectric film according to claim 1,
wherein a resistance value of a laminate of the interlayer and the electrode layer is 12Ω or less.

4. The piezoelectric film according to claim 1,
wherein the interlayer is provided on only one side between the electrode layers and the piezoelectric layer.

5. The piezoelectric film according to claim 1, further comprising:
a protective layer provided on a surface of at least one of the electrode layers.

6. The piezoelectric film according to claim 1,
wherein the piezoelectric film is polarized in a thickness direction.

7. The piezoelectric film according to claim 1,
wherein the piezoelectric film has no in-plane anisotropy as a piezoelectric characteristic.

8. The piezoelectric film according to claim 1, further comprising:
a lead-out wire which connects the electrode layers and an external power source.

9. A laminated piezoelectric element formed by laminating a plurality of layers of the piezoelectric films according to claim 1.

10. The laminated piezoelectric element according to claim 9,
wherein the piezoelectric films are polarized in a thickness direction, and polarization directions of adjacent piezoelectric films are opposite to each other.

11. The laminated piezoelectric element according to claim 9,
wherein the laminated piezoelectric element is formed by laminating a plurality of layers of the piezoelectric films by folding back the piezoelectric film one or more times.

12. The laminated piezoelectric element according to claim 9, comprising:
a bonding layer which bonds the adjacent piezoelectric films.

13. The piezoelectric film according to claim 2,
wherein a resistance value of a laminate of the interlayer and the electrode layer is 12Ω or less.

14. The piezoelectric film according to claim 2,
wherein the interlayer is provided on only one side between the electrode layers and the piezoelectric layer.

15. The piezoelectric film according to claim 2, further comprising:
a protective layer provided on a surface of at least one of the electrode layers.

16. The piezoelectric film according to claim 2,
wherein the piezoelectric film is polarized in a thickness direction.

17. The piezoelectric film according to claim 2,
wherein the piezoelectric film has no in-plane anisotropy as a piezoelectric characteristic.

18. The piezoelectric film according to claim 2, further comprising:
a lead-out wire which connects the electrode layers and an external power source.

19. A laminated piezoelectric element formed by laminating a plurality of layers of the piezoelectric films according to claim 2.

20. The laminated piezoelectric element according to claim 19,
wherein the piezoelectric films are polarized in a thickness direction, and polarization directions of adjacent piezoelectric films are opposite to each other.
